(19) United States
(12) Patent Application Publication
(10) Pub. No.: US 2024/0170599 A1
(43) Pub. Date: May 23, 2024

(54) SILICON-BASED HETERO-JUNCTION SOLAR CELL AND PHOTOVOLTAIC MODULE

(71) Applicant: JIANGSU CLELO TECHNOLOGIES CO., LTD., Changshu (CN)

(72) Inventors: Leizhen Hu, Changshu City (CN); Huiguo Zhang, Changshu City (CN); Silin Meng, Dongtai City (CN); Changrong Zhang, Changshu City (CN); Zhiguang Zhang, Hefeng County (CN)

(21) Appl. No.: 18/513,268

(22) Filed: Nov. 17, 2023

(30) Foreign Application Priority Data
Nov. 21, 2022 (CN) 202223075596.0

(51) Int. Cl. H01L 31/0747; H01L 31/0216; H01L 31/0224; H01L 31/05

(52) U.S. Cl. CPC H01L 31/0747; H01L 31/02167; H01L 31/022425; H01L 31/0512

(57) ABSTRACT

A silicon-based hetero-junction solar cell and a photovoltaic module and methods for making and using same. The cell includes an intrinsic amorphous silicon layer located on a surface of an N-type monocrystalline silicon wafer, a doped layer located on a surface of the intrinsic amorphous silicon layer, and a conductive film located on a surface of the doped layer. A metal electrode is arranged on the conductive film. The metal electrode includes a copper-based layer arranged on the conductive film and a tin layer coated on a surface of the copper-based layer. A low-temperature copper slurry is used instead of a low-temperature silver slurry, thereby greatly reducing preparation costs. Electroplating a layer of tin on a surface of the copper electrode can achieve good soldering with a tin-plated copper solder ribbon, protect the surface of the copper electrode, and increase electrode compactness to effectively improve the conductive performance.

### CROSS-REFERENCE TO RELATED APPLICATIONS

This application claims the benefit of, and priority under 35 U.S.C. § 119 to, Chinese Utility Model Patent Application No. 202223075596.0, filed Nov. 21, 2022, the disclosure of which is hereby incorporated herein by reference in its entirety and for all purposes.

### FIELD OF TECHNOLOGY

The present disclosure relates to the field of solar cells and more specifically, but not exclusively, to a silicon-based hetero-junction solar cell and a photovoltaic module.

### BACKGROUND

A solar cell is a photovoltaic device that can effectively absorb solar energy and convert the solar energy into electrical energy. At present, crystalline silicon solar cells are most widely used products. Silicon-based hetero-junction solar cells have the highest photoelectric conversion efficiency and greatest development potential based on existing mass production technologies.

A metal electrode of a conventional silicon-based hetero-junction solar cell is generally prepared using a screen printing technology. To be specific, a low-temperature silver slurry is printed on a front surface and a back surface of the cell through screen printing and solidified at a temperature of 180° C. to 200° C. for ten to thirty minutes to form the metal electrode. This method involves screen printing the low-temperature silver slurry to prepare the metal electrode and requires high costs, which account for about forty percent of non-silicon processing costs. A method of directly preparing a copper electrode using an electroplating technology is also used in the industry. However, copper electroplating involves many steps. Although copper is used instead of silver, processing costs are still about one half of costs of printing a silver electrode.

### SUMMARY

The disclosure provides an improved silicon-based hetero-junction solar cell and a photovoltaic module. A tin layer is attached to a surface of a pure copper electrode to achieve good soldering with a tin-plated copper solder ribbon, thereby reducing preparation costs of a metal electrode of a cell.

A silicon-based hetero-junction solar cell is provided, including an intrinsic amorphous silicon layer located on a surface of an N-type monocrystalline silicon wafer;
a doped layer located on a surface of the intrinsic amorphous silicon layer; and
a conductive film located on a surface of the doped layer,
wherein a metal electrode is arranged on the conductive film and comprises a copper-based layer arranged on the conductive film and a tin layer coated on a surface of the copper-based layer.

In some embodiments, a thickness of the tin layer is five percent (5%) to fifteen percent (15%) of an overall thickness of the metal electrode.

In some embodiments, the tin layer is electroplated on the surface of the copper-based layer.

In some embodiments, the copper-based layer covers on a surface of the conductive film.

In some embodiments, the copper-based layer is printed, transferred or sprayed on the surface of the conductive film.

In some embodiments, an upper surface of the N-type monocrystalline silicon wafer comprises a first intrinsic amorphous silicon layer, a first doped layer, a first conductive film, a first metal electrode, and a first tin layer in sequence from bottom to top, and
a lower surface of the N-type monocrystalline silicon wafer comprises a second intrinsic amorphous silicon layer, a second doped layer, a second conductive film, a second metal electrode, and a second tin layer in sequence from top to bottom.

In some embodiments, the doped layer comprises phosphorus or boron: the first doped layer is doped with phosphorus, and the second doped layer is doped with boron: or the first doped layer is doped with boron, and the second doped layer is doped with phosphorus.

In some embodiments, a thickness of the conductive film is ninety nanometers (90 nm) to one hundred and twenty nanometers (120 nm).

The following technical solution is further used in the disclosure:

A photovoltaic module, including the solar cell described above.

In some embodiments, first and second adjacent solar cells are concatenated through one or more tin-plated copper solder ribbons, a first end portion of the tin-plated copper solder ribbon being soldered to the tin layer of the metal electrode on a front surface of the first adjacent solar cell, and a second end portion of the tin-plated copper solder ribbon being soldered to the tin layer of the metal electrode on a back surface of the second adjacent solar cell.

The foregoing solutions of the disclosure have the following advantages.

In the silicon-based hetero-junction solar cell in the disclosure, a low-temperature copper slurry is used instead of a low-temperature silver slurry to prepare a metal electrode, thereby greatly reducing preparation costs of the metal electrode. Electroplating a layer of tin on a surface of the copper electrode can achieve good soldering with a tin-plated copper solder ribbon, provide an effect of protecting the surface of the copper electrode, and increase electrode compactness to effectively improve the conductive performance.

### BRIEF DESCRIPTION OF THE DRAWINGS

To describe the technical solutions of the disclosure more clearly, the following briefly describes the drawings required for describing the embodiments. Apparently, the drawings in the following description show merely some embodiments of the disclosure, and those of ordinary skill in the art may still derive other drawings from these drawings without creative efforts.

FIG. 1 is a schematic structural diagram of a silicon-based hetero-junction solar cell according to an embodiment of the disclosure: and

FIG. 2 is a schematic diagram showing connection between a solar cell and a tin-plated copper solder ribbon according to an embodiment of the disclosure.

In the drawings: 1—cell: 11—N-type monocrystalline silicon wafer: 12—first intrinsic amorphous silicon layer: 13—first doped layer: 14—first conductive film: 15—first metal electrode: 151—first copper-based layer: 152—first tin layer: 16—second intrinsic amorphous silicon layer: 17—second doped layer: 18—second conductive film: 19—second metal electrode: 191—second copper-based layer: 192—second tin layer: 21—cell body: and 22—tin-plated copper solder ribbon.

### DETAILED DESCRIPTION OF THE PREFERRED EMBODIMENTS

Example embodiments of a silicon-based hetero-junction solar cell and a photovoltaic module are described in detail below in conjunction with the accompanying drawings, so that advantages and features set forth in the present disclosure can be more easily understood by those skilled in the art. It should be noted herein that the description of these embodiments is used for helping understand the disclosure, but is not intended to limit the disclosure. In addition, the technical features involved in the embodiments of the disclosure described below may be combined with each other as long as they do not conflict with each other.

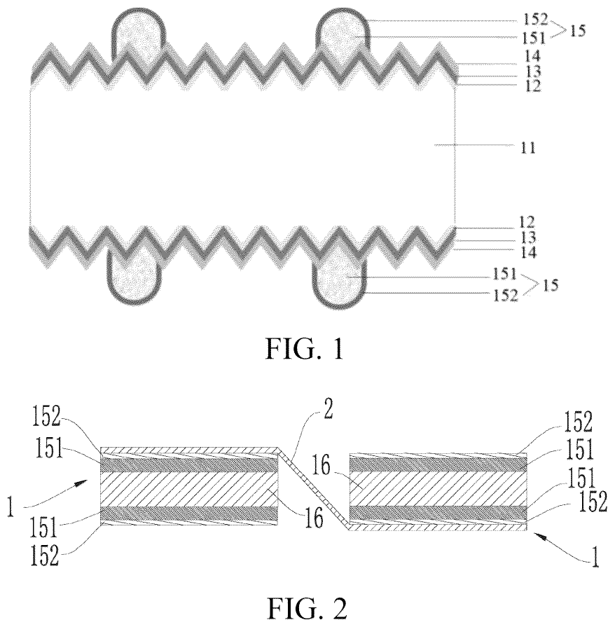

As shown in FIG. 1 and FIG. 2, a silicon-based hetero-junction solar cell according to an embodiment includes an N-type monocrystalline silicon wafer 11, an intrinsic amorphous silicon layer located on a surface of the N-type monocrystalline silicon wafer 11, a doped layer located on a surface of the intrinsic amorphous silicon layer, and a conductive film located on a surface of the doped layer. A metal electrode is arranged on the conductive film. The metal electrode includes a copper-based layer arranged on the conductive film and a tin layer coated on a surface of the copper-based layer. Specifically, an upper surface of the N-type monocrystalline silicon wafer 11 includes a first intrinsic amorphous silicon layer 12, a first doped layer 13, a first conductive film 14, a first metal electrode 15, and a first tin layer 152 in sequence from bottom to top. A lower surface of the N-type monocrystalline silicon wafer 11 includes a second intrinsic amorphous silicon layer 16, a second doped layer 17, a second conductive film 18, a second metal electrode 19, and a second tin layer 192 in sequence from top to bottom.

A specification of the N-type monocrystalline silicon wafer 11 may be 182 mm*182 mm, 210 mm*210 mm, 182 mm*91 mm, 210 mm*105 mm, or other sizes. In this embodiment, an alkaline solution is used to prepare a pyramid textured structure on the surface of the N-type monocrystalline silicon wafer 11, and the intrinsic amorphous silicon layer and the doped layer are sequentially deposited on the surface of the textured N-type monocrystalline silicon wafer 11 through plasma chemical vapor deposition. The doped layer may be a doped amorphous silicon film layer or a doped microcrystalline silicon film layer. The doped layer is doped with phosphorus or boron. A doping type of the doped layer in the upper surface is different from that of the doped layer in the lower surface. To be specific, if the first doped layer 13 is doped with phosphorus, the second doped layer 17 is doped with boron. Alternatively, if the first doped layer 13 is doped with boron, the second doped layer 17 is doped with phosphorus.

The conductive film on the surface of the doped layer is deposited through magnetron sputtering or evaporation. A thickness of the conductive film is controlled to be between ninety nanometers (90 nm) and one hundred and twenty nanometers (120 nm). The metal electrode on the conductive film is prepared from a low-temperature copper slurry through means such as screen printing, laser transfer, or inkjet, and cured a curing oven at a curing temperature controlled at 180° C. to 200° C. for ten to thirty minutes to form a copper metal electrode. A first copper-based layer 151 of the first metal electrode 15 covers the surface of the first conductive film 14. The first tin layer 152 is electroplated on the surface of the first copper-based layer 151. A second copper-based layer 191 of the second metal electrode 19 covers the surface of the second conductive film 18. The second tin layer 192 is electroplated on the surface of the second copper-based layer 191. A thickness of the tin layer is five percent to fifteen percent of an overall thickness of the metal electrode. A width of an electrode grid line can be between ten micrometers (10 μm) and forty micrometers (40 μm).

As shown in FIG. 2, an embodiment further provides a photovoltaic module. Two adjacent solar cells 1 in the photovoltaic module are concatenated through one or more tin-plated copper solder ribbons 22. One end portion, such as a first end portion, of the tin-plated copper solder ribbon 22 can be soldered to the tin layer of the metal electrode 15 on a front surface of one solar cell 1. Another end portion, such as a second end portion, of the tin-plated copper solder ribbon 22 can be soldered to the tin layer of the metal electrode on a back surface of the other solar cell 1. A plurality of solar cells 1 are sequentially soldered through tin-plated copper solder ribbons 22 in a similar manner to form a cell string.

Based on the above, in the silicon-based hetero-junction solar cell in the disclosure, a low-temperature copper slurry is used instead of a low-temperature silver slurry to prepare a metal electrode, thereby greatly reducing preparation costs of the metal electrode. Electroplating a layer of tin on a surface of the copper electrode can achieve good soldering with a tin-plated copper solder ribbon, provide an effect of protecting the surface of the copper electrode, and increase electrode compactness to effectively improve the conductive performance.

As used in the specification and claims, the terms “comprise”, “include” and variants thereof merely imply the inclusion of clearly identified steps and elements, such steps and elements are not to be construed as an exclusive enumeration, and the method or device may also include other steps or elements. The term “and/or” used in the specification includes any one or any combination of one or more related listed items.

It should be noted that, unless otherwise particularly specified, a feature is “fixed” or “connected” to another feature may mean that the feature is directly fixed or connected to the another feature, or indirectly fixed or connected to the another feature. In addition, the terms such as up, down, left, and right used in the disclosure are merely based on the relationship between relative positions of various components of the disclosure in the drawings

The foregoing embodiment is merely for illustrating the technical concept and features of the disclosure, is an example embodiment for enabling those skilled in the art to understand and implement the content of the disclosure, and is not intended to limit the protection scope of the disclosure. Any equivalent variation or modification made based on the principles of the disclosure shall fall within the protection scope of the disclosure.

What is claimed is:

1. A silicon-based hetero-junction solar cell, comprising:
an intrinsic amorphous silicon layer located on a surface of an N-type monocrystalline silicon wafer;
a doped layer located on a surface of the intrinsic amorphous silicon layer; and
a conductive film located on a surface of the doped layer,
wherein a metal electrode is arranged on the conductive film and comprises a copper-based layer arranged on the conductive film and a tin layer coated on a surface of the copper-based layer.

2. The silicon-based hetero-junction solar cell according to claim 1, wherein a thickness of the tin layer is between five percent and fifteen percent of an overall thickness of the metal electrode.

3. The silicon-based hetero-junction solar cell according to claim 1, wherein the tin layer is electroplated on the surface of the copper-based layer.

4. The silicon-based hetero-junction solar cell according to claim 1, wherein the copper-based layer covers a surface of the conductive film.

5. The silicon-based hetero-junction solar cell according to claim 4, wherein the copper-based layer is printed on the surface of the conductive film.

6. The silicon-based hetero-junction solar cell according to claim 4, wherein the copper-based layer is transferred on the surface of the conductive film.

7. The silicon-based hetero-junction solar cell according to claim 4, wherein the copper-based layer is sprayed on the surface of the conductive film.

8. The silicon-based hetero-junction solar cell according to claim 1,
wherein an upper surface of the N-type monocrystalline silicon wafer comprises a first intrinsic amorphous silicon layer, a first doped layer, a first conductive film, a first metal electrode, and a first tin layer in sequence from bottom to top, and
wherein a lower surface of the N-type monocrystalline silicon wafer comprises a second intrinsic amorphous silicon layer, a second doped layer, a second conductive film, a second metal electrode, and a second tin layer in sequence from top to bottom.

9. The silicon-based hetero-junction solar cell according to claim 8,
wherein the first doped layer is doped with phosphorus, and
wherein the second doped layer is doped with boron.

10. The silicon-based hetero-junction solar cell according to claim 8,
wherein the first doped layer is doped with boron, and
wherein the second doped layer is doped with phosphorus.

11. The silicon-based hetero-junction solar cell according to claim 1, wherein a thickness of the conductive film is between ninety nanometers and one hundred and twenty nanometers.

12. A photovoltaic module, comprising a plurality of solar cells each being provided according to claim 1.

13. The photovoltaic module according to claim 12, wherein first and second adjacent solar cells are concatenated through one or more tin-plated copper solder ribbons, a first end portion of the tin-plated copper solder ribbon being soldered to the tin layer of the metal electrode on a front surface of the first adjacent solar cell, and a second end portion of the tin-plated copper solder ribbon being soldered to the tin layer of the metal electrode on a back surface of the second adjacent solar cell.

14. The photovoltaic module according to claim 13, wherein the first and second end portions of the tin-plated copper solder ribbon comprise opposite end portions of the tin-plated copper solder ribbon.

15. The photovoltaic module according to claim 12, wherein a thickness of the tin layer of each solar cell is between five percent and fifteen percent of an overall thickness of the metal electrode.

16. The photovoltaic module according to claim 12, wherein the tin layer of each solar cell is electroplated on the surface of the copper-based layer.

17. The photovoltaic module according to claim 12, wherein the copper-based layer of each solar cell covers a surface of the conductive film.

18. The photovoltaic module according to claim 17, wherein the copper-based layer of each solar cell is printed on the surface of the conductive film.

19. The photovoltaic module according to claim 17, wherein the copper-based layer of each solar cell is transferred on the surface of the conductive film.

20. The photovoltaic module according to claim 17, wherein the copper-based layer of each solar cell is sprayed on the surface of the conductive film.
